(19) United States
(12) Patent Application Publication
(10) Pub. No.: US 2026/0095145 A1
(43) Pub. Date: Apr. 2, 2026

(54) MULTI-LAYER PIEZOELECTRIC SUBSTRATE

(71) Applicant: Skyworks Solutions, Inc., Irvine, CA (US)

(72) Inventor: Cedric Olivier Gerald Poirel, Irvine, CA (US)

(21) Appl. No.: 19/347,618

(22) Filed: Oct. 1, 2025

Related U.S. Application Data
(60) Provisional application No. 63/702,577, filed on Oct. 2, 2024.

(51) Int. Cl. H03H 9/05; H03H 3/08; H03H 9/10; H03H 9/25

(52) U.S. Cl. CPC H03H 9/0561; H03H 3/08; H03H 9/1092; H03H 9/25

(57) ABSTRACT

An acoustic wave device includes a multi-layer piezoelectric substrate with an electrical interconnect extending through a piezoelectric layer and a dielectric layer. At least one electrical connection extends through a substrate layer and is electrically connected with the electrical interconnect.

### INCORPORATION BY REFERENCE TO ANY PRIORITY APPLICATION

Any and all applications for which a foreign or domestic priority claim is identified in the Application Data Sheet as filed with the present application are hereby incorporated by reference under 37 CFR 1.57.

### BACKGROUND

### Field

The present disclosure generally relates to multi-layer piezo substrates and manufacturing method thereof, and particularly to multi-layer piezo substrates and manufacturing method thereof for bulk acoustic wave devices.

### Description of Related Art

Interconnects play vital roles in modern semiconductor devices, particularly for integrated circuit (IC)-based devices. Typical interconnects are typically positioned on the die area for integration. However, such placement of interconnects poses several limitations.

For example, allocating die space for interconnects leads to reduction of the effective area available for the placement of active components and/or materials, which limits the complexity and functionality of such devices. In particular, in applications utilizing acoustic properties, such as bulk acoustic wave (BAW) or surface acoustic wave (SAW) devices, the larger space occupied by interconnects, in turn, means smaller available space for acoustic components and/or materials. Implementing alternative designs by repositioning acoustic components and/or materials in acoustic devices is difficult as, in many cases, these components must be located on top due to their inherent nature of acoustic devices.

Furthermore, known redistribution layers (RDLs) used to reroute electronic signals from densely packed die areas to more accessible package areas also introduce several drawbacks, such as increased manufacturing complexity which, in turn, leads to higher production costs and longer fabrication processes.

In addition, a drawback also arises from the mismatch in coefficients of thermal expansion (CTEs) of materials used within such devices, which can limit die sizes and package reliability.

### SUMMARY

In some aspects, the techniques described herein relate to a multi-layer piezoelectric substrate including: a piezoelectric layer; at least one dielectric layer; at least one electrical interconnect extending through the piezoelectric layer and the at least one dielectric layer; and a substrate layer having at least one electrical connection extending through the substrate layer, the at least one electrical connection and the at least one electrical interconnect being electrically connected.

In some aspects, the techniques described herein relate to a multi-layer piezoelectric substrate further including at least one first electrode on a first side of the substrate.

In some aspects, the techniques described herein relate to a multi-layer piezoelectric substrate wherein the at least one first electrode is electrically connected with the at least one electrical connection via the at least one electrical interconnect.

In some aspects, the techniques described herein relate to a multi-layer piezoelectric substrate wherein the at least one first electrode is physically coupled to the at least one electrical interconnect.

In some aspects, the techniques described herein relate to a multi-layer piezoelectric substrate wherein the first side of the substrate corresponds to a side of the piezoelectric layer.

In some aspects, the techniques described herein relate to a multi-layer piezoelectric substrate wherein the at least one first electrode is an interdigital transducer.

In some aspects, the techniques described herein relate to a multi-layer piezoelectric substrate further including at least one second electrode on a second side of the substrate.

In some aspects, the techniques described herein relate to a multi-layer piezoelectric substrate wherein the at least one second electrode being electrically connected with the at least one electrical interconnect via the at least one electrical connection.

In some aspects, the techniques described herein relate to a multi-layer piezoelectric substrate wherein the at least one second electrode is physically coupled to the at least one electrical connection.

In some aspects, the techniques described herein relate to a multi-layer piezoelectric substrate wherein the second side of the substrate corresponds to a side of the substrate layer.

In some aspects, the techniques described herein relate to a multi-layer piezoelectric substrate wherein the at least one second electrode is an electrical terminal.

In some aspects, the techniques described herein relate to a multi-layer piezoelectric substrate including a plurality of the electrical terminals on the second side of the multi-layer piezoelectric substrate, each of the electrical terminals being electrically connected with the at least one first electrode on a first side of the multi-layer piezoelectric substrate via the at least one electrical interconnect and the at least one electrical connection, the first side of the multi-layer piezoelectric substrate facing away from the second side of the multi-layer piezoelectric substrate.

In some aspects, the techniques described herein relate to a multi-layer piezoelectric substrate further including at least one bonding layer for providing physical coupling with one or more adjacent layers, the at least one electrical interconnect extending through the piezoelectric layer, the at least one dielectric layer, and the at least one bonding layer.

In some aspects, the techniques described herein relate to a multi-layer piezoelectric substrate wherein the at least one bonding layer includes SiO2, Si3N4, and/or SiC SiO2.

In some aspects, the techniques described herein relate to a multi-layer piezoelectric substrate wherein one or more of the at least one dielectric layer form the at least one bonding layer.

In some aspects, the techniques described herein relate to a multi-layer piezoelectric substrate including a first dielectric layer, a second dielectric layer, and a polysilicon layer between the first dielectric layer and the second dielectric layer.

In some aspects, the techniques described herein relate to a multi-layer piezoelectric substrate wherein at least one of the first dielectric layer and/or the second dielectric layer is configured to function as a bonding layer for providing physical coupling with one or more adjacent layers.

In some aspects, the techniques described herein relate to a multi-layer piezoelectric substrate wherein the first dielectric layer is positioned between the piezoelectric layer and the polysilicon layer, and the second dielectric layer is positioned between the polysilicon layer and the substrate layer.

In some aspects, the techniques described herein relate to a multi-layer piezoelectric substrate including: one or more first electrical interconnects extending through the piezoelectric layer, the first dielectric layer, and the polysilicon layer; and one or more second electrical interconnects extending through the second dielectric layer.

In some aspects, the techniques described herein relate to a multi-layer piezoelectric substrate wherein the one or more first electrical interconnects are electrically connected with the at least one electrical connection via the one or more second electrical interconnects.

In some aspects, the techniques described herein relate to a multi-layer piezoelectric substrate wherein one or more of the at least one electrical connection are electrical via(s).

According to a number of embodiments, an acoustic wave device comprising the multi-layer piezoelectric substrate is provided.

According to a number of embodiments, a die comprising the acoustic wave device is provided.

According to a number of embodiments, a filter comprising one or more of the acoustic wave devices is provided.

According to a number of embodiments, a radio-frequency module is provided, the radio-frequency module comprising: a packaging substrate configured to receive a plurality of devices; and a die mounted on the packaging substrate, the die comprising the acoustic wave device.

According to a number of embodiments, a wireless mobile device is provided, the wireless mobile device comprising: one or more antennas; and a radio-frequency module that communicates with the one or more antennas, the radio-frequency module comprising a packaging substrate configured to receive a plurality of devices; and the die mounted on the packaging substrate.

In some aspects, the techniques described herein relate to a method of forming a multi-layer piezoelectric substrate, the method including the steps of: aligning at least one electrical interconnect of a first part of the multi-layer piezoelectric substrate and at least one electrical interconnect of a second part of the multi-layer piezoelectric substrate by brining said electrical interconnects into contact, the first part of the multi-layer piezoelectric substrate including a substrate layer, at least one electrical connection extending through the substrate layer, at least one first dielectric layer, and the at least one electrical interconnect extending through the at least one dielectric layer, and the second part of the multi-layer piezoelectric substrate including a piezoelectric layer and the least one electrical interconnect extending through the piezoelectric layer; and bonding the first part of the multi-layer piezoelectric substrate and the second part of the multi-layer piezoelectric substrate.

In some aspects, the techniques described herein relate to a method wherein the first part of the multi-layer piezoelectric substrate is formed by steps including: forming the at least one electrical connection extending through the substrate layer; forming the at least one first dielectric layer; and forming the at least one electrical interconnect extending through the at least one dielectric layer.

In some aspects, the techniques described herein relate to a method further including the step of forming at least one electrode on a side of the substrate layer.

In some aspects, the techniques described herein relate to a method wherein the at least one electrode is electrically connected with the at least one electrical interconnect via the at least one electrical connection.

In some aspects, the techniques described herein relate to a method wherein the at least one electrode is physically coupled to the at least one electrical connection.

In some aspects, the techniques described herein relate to a method wherein the at least one electrode is an electrical terminal.

In some aspects, the techniques described herein relate to a method wherein the second part of the multi-layer piezoelectric substrate is formed by steps including: forming the piezoelectric layer; and forming the at least one electrical interconnect extending through the piezoelectric layer.

In some aspects, the techniques described herein relate to a method wherein the piezoelectric layer is formed on a substrate.

In some aspects, the techniques described herein relate to a method further including the step of removing the substrate on which the piezoelectric layer is formed after the step of bonding of the first and second parts of multi-layer piezoelectric substrate.

In some aspects, the techniques described herein relate to a method wherein the substrate on which the piezoelectric layer is removed by means of milling and/or lift-off.

In some aspects, the techniques described herein relate to a method wherein the second part of the multi-layer piezoelectric substrate includes one or more sacrificial layers for the milling and/or lift-off.

In some aspects, the techniques described herein relate to a method wherein the second part of the multi-layer piezoelectric substrate is a front-end portion of the multi-layer piezoelectric substrate.

In some aspects, the techniques described herein relate to a method wherein forming the second part of the multi-layer piezoelectric substrate includes the steps of: performing lithography or etching techniques to form one or more openings through the second part of the multi-layer piezoelectric substrate; and depositing one or more conductive materials to form the electrical interconnect(s) extending through the second part of the multi-layer piezoelectric substrate.

In some aspects, the techniques described herein relate to a method wherein forming the second part of the multi-layer piezoelectric substrate includes the steps of: performing lithography or etching techniques to form one or more voids on a surface of the piezoelectric layer; and depositing one or more conductive materials on the one or more voids to form one or more buried electrodes on the surface of the piezoelectric layer.

In some aspects, the techniques described herein relate to a method further including the step of forming at least one electrode on a side of piezoelectric layer.

In some aspects, the techniques described herein relate to a method wherein the at least one electrode is formed for electrical connection with the at least one electrical interconnect.

In some aspects, the techniques described herein relate to a method wherein the at least one electrode is formed for physical coupling to the at least one electrical interconnect.

In some aspects, the techniques described herein relate to a method wherein the at least one electrode is an interdigital transducer.

In some aspects, the techniques described herein relate to a method wherein the first part and/or second part of the multi-layer piezoelectric substrate includes one or more layers configured to function as bonding layer(s) for bonding the first and second parts of multi-layer piezoelectric substrate.

In some aspects, the techniques described herein relate to a method wherein the at least one electrical connection extending through the substrate layer, the at least one electrical interconnect extending through the at least one dielectric layer, and/or the at least one electrical interconnect extending through the piezoelectric layer are/is formed prior to the step of bonding of the first and second parts of multi-layer piezoelectric substrate.

In some aspects, the techniques described herein relate to a method wherein the at least one electrical connection extending through the substrate layer, the at least one electrical interconnect extending through the at least one dielectric layer, and/or the at least one electrical interconnect extending through the piezoelectric layer are/is formed after the step of bonding of the first and second parts of multi-layer piezoelectric substrate.

In some aspects, the techniques described herein relate to a method for forming an acoustic wave device, the method including the steps of: forming a multi-layer piezoelectric substrate, the step of forming multi-layer piezoelectric substrate including: providing a first part of the multi-layer piezoelectric substrate including a substrate layer, at least one electrical connection extending through the substrate layer, at least one first dielectric layer, and at least one electrical interconnect extending through the at least one dielectric layer, providing a second part of the multi-layer piezoelectric substrate including a piezoelectric layer and at least one electrical interconnect extending through the piezoelectric layer, and bonding the first and second parts of multi-layer piezoelectric substrate to align the at least one electrical interconnect extending through the at least one dielectric layer and the at least one electrical interconnect extending through the piezoelectric layer; and forming one or more acoustic wave device components on the multi-layer piezoelectric substrate.

In some aspects, the techniques described herein relate to a method wherein the one or more acoustic wave device components are one or more resonator structures.

In some aspects, the techniques described herein relate to a method wherein the one or more acoustic wave device components are one or more bulk acoustic wave device components.

In some aspects, the techniques described herein relate to a method wherein the one or more acoustic wave device components are one or more film bulk acoustic resonator components.

In some aspects, the techniques described herein relate to a method wherein the one or more acoustic wave device components are one or more solidly mounted resonator components.

In some aspects, the techniques described herein relate to a method wherein the one or more acoustic wave device components are one or more surface acoustic wave device components.

In some aspects, the techniques described herein relate to a method wherein the one or more acoustic wave device components are one or more electrical connections and/or electrodes.

In some aspects, the techniques described herein relate to a method wherein the one or more acoustic wave device components are one or more cavity packages.

Embodiments disclosed herein may address various problems. One or more embodiments may address one or more of the problems concerning the effective area available for the placement of components and/or materials, device production costs, complexity of device fabrication processes, device sizes, and/or device reliability.

### BRIEF DESCRIPTION OF THE DRAWINGS

Various aspects of at least one embodiment are discussed below with reference to the accompanying figures, which are not intended to be drawn to scale. The figures are included to provide illustration and a further understanding of the various aspects and embodiments, and are incorporated in and constitute a part of this specification, but are not intended as a definition of the limits of the invention. In the figures, each identical or nearly identical component that is illustrated in various figures is represented by a like numeral. For purposes of clarity, not every component may be labeled in every figure. In the figures:

FIG. 1 is a cross-sectional view of an exemplary acoustic wave device comprising a multi-layer piezoelectric substrate, according to an embodiment;

FIG. 2A is a cross-sectional view of an exemplary multi-layer piezoelectric substrate, according to an embodiment;

FIG. 2B is a flow chart illustrating exemplary steps for forming a multi-layer piezoelectric substrate, according to an embodiment;

FIG. 2C is a flow chart illustrating exemplary steps for forming a first part of the multi-layer piezoelectric substrate, according to an embodiment;

FIG. 2D is a flow chart illustrating exemplary steps for forming a second part of the multi-layer piezoelectric substrate, according to an embodiment;

FIG. 3 is a radio-frequency front end module according to aspects of the present invention; and

FIG. 4 is a wireless device according to aspects of the present invention.

### DETAILED DESCRIPTION

The following detailed description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Generally embodiments of the invention may provide a multi-layer piezoelectric substrate comprising: a piezoelectric layer 122; at least one dielectric layer 124; at least one electrical interconnect 114 extending through the piezoelectric layer 122 and the at least one dielectric layer 124; and a substrate layer 128 having at least one electrical connection 116 extending through the substrate layer 128, the at least one electrical connection 116 and the at least one electrical interconnect 114 being electrically connected. Embodiments of the invention may also provide an acoustic wave device comprising said multi-layer piezoelectric substrate.

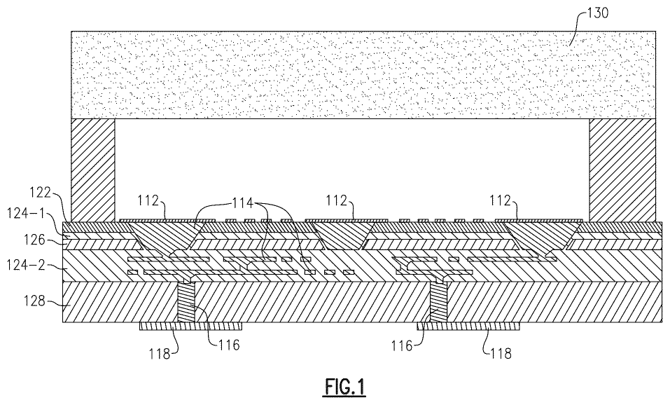

Although the device in FIG. 1 is an acoustic wave device having a cavity package 130, it will be appreciated that, in other embodiments, the acoustic wave device may not comprise such a cavity package. Similarly, it will also be appreciated that the structure and fabrication method presented herein may also be applied in other types of semiconductor devices and/or integrated circuits (ICs) that are not acoustic wave devices. Furthermore, the acoustic wave device may, optionally, comprise substrate(s), redistribution layer(s) (RDLs) and/or interconnect(s) having a plurality of different shapes and dimensions depending on factors, including the shape and dimensions of the acoustic wave device, physical space available within the device structure, and desired acoustic and electrical properties of the acoustic wave device.

Embodiments of the acoustic wave device will be discussed with reference to example cross-sectional view of FIG. 1.

FIG. 1 illustrates a cross-sectional view of an exemplary acoustic wave device comprising a multi-layer piezoelectric substrate. As shown in FIG. 1, the multi-layer piezoelectric substrate comprises a piezoelectric layer 122, at least one dielectric layer 124 and a substrate layer 128.

In the example shown in FIG. 1 the multi-layer piezoelectric substrate comprises two dielectric layers 124-1, 124-2. However, it will be appreciated that, in other embodiments, the multi-layer piezoelectric substrate may comprise only one dielectric layer 124, or more than two dielectric layer 124. Similarly, although the dielectric layers 124-1, 124-2 in the example of FIG. 1 are made of silicon dioxide (SiO₂), in other embodiments, the one or more dielectric layers 124 may be made of or may comprise any suitable dielectric materials, such as SiO₂, silicon nitride (Si₃N₄), and/or silicon carbide (SiC). Furthermore, in the embodiments comprising a plurality of the dielectric layers 124, the multi-layer piezoelectric substrate may comprise the dielectric layers 124 made of different materials.

In the example shown in FIG. 1 the multi-layer piezoelectric substrate also comprises an optional polysilicon (poly-Si) layer 128 between the two dielectric layers 124-1, 124-2. The poly-Si layer 128 may provide a trap-rich layer. Alternatively, instead or in conjunction with the poly-Si layer 128, the multi-layer piezoelectric substrate may comprise a high-impedance layer. Such a high-impedance layer may, for example, comprise Si₃N₄ and/or AlN.

As shown FIG. 1, the piezoelectric layer 122 has at least one electrical interconnect 114 extending through the thickness of the piezoelectric layer 122. The at least one electrical interconnect 114 also extends through the thickness of the at least one dielectric layer 124. Optionally, at least a part of the at least one electrical interconnect 114 may be provided in forms of one or more redistribution layer (RDL).

Optionally, the at least one electrical interconnect 114 may be divided into a plurality of sub-sections. In such cases, each of the sub-sections may extend through the thickness of one or more layers. Optionally, the electrical interconnects 114 in different sub-sections may have geometries, dimensions, and/or shapes. For example, in the example of FIG. 1, a first sub-section of the electrical interconnects 114 extend through the thickness of the piezoelectric layer 122, the upper dielectric layer 124-1, and the optional poly-Si 126 layer; and a second sub-section of the electrical interconnects 114 extend through the thickness of the lower dielectric layer 124-2. Optionally, the sub-sections may be electrically connected by physical coupling (i.e. by one or more direct physical contacts) or be electrically connected via any suitable type of electrical connections.

Optionally, at least a part of the at least one electrical interconnect 114 may have geometries, dimensions, and/or shapes for enabling easy and reliable coupling with adjacent electrical connections. For example, as shown in the example of FIG. 1, the electrical interconnects 114 in the first sub-section (i.e. the upper section) may be shaped so that they have larger dimensions at the surface of the piezoelectric layer 122 to enable easy and reliable coupling with the electrodes and/or interdigital transducers (IDTs) 112 at the surface of the piezoelectric layer 122. Similarly, as shown in the example of FIG. 1, the electrical interconnects 114 in the first sub-section (i.e. the upper section) may be shaped so that they have smaller dimensions at the interface of the first and second sub-sections, which may be particularly useful if the electrical interconnects 114 in the second sub-section is densely distributed or of smaller dimensions compare to the electrodes and/or IDTs 112.

Similarly, one or more of the electrical interconnects 114 within a single layer or a section, may optionally have varying geometries, dimensions, and/or shapes. For example, as shown in the example of FIG. 1, the electrical interconnects 114 within the lower dielectric layer 124-2 may have one or more upper ends having varying geometries, dimensions, and/or shapes for enabling easy and/or reliable coupling with the electrical connections 114, 116 of the adjacent layer(s) 126, 128.

Optionally, the electrical interconnects 114 may be divided into a plurality of sub-sets. In such cases, the sub-sets may not be electrically connected with each other within the thickness of the multi-layer piezoelectric substrate, and instead, may be connected via electrical connection located on the multi-layer piezoelectric substrate or outside the thickness of the multi-layer piezoelectric substrate. For example, a first sub-set of the electrical interconnects 114 (i.e. leftmost sub-set of electrical interconnects 114 of FIG. 1) may not be electrically connected with a second sub-set of the electrical interconnects 114 (i.e. rightmost sub-set of electrical interconnects 114 of FIG. 1) within the thickness of the multi-layer piezoelectric substrate, and instead, the electrical connection between the two sub-sets of electrical interconnects 114 may be via one or more electrodes 112 positioned on the multi-layer piezoelectric substrate (e.g. one or more an interdigital transducers 112 of FIG. 1).

Thus, the multi-layer piezoelectric substrate provides a substrate or platform within which electrical paths can be routed and/or distributed. This obviates or reduces the needs for having a dedicated RDL on the die space, thereby increasing the effective die space available for other components. The multi-layer piezoelectric substrate also obviates or reduces the need for integrating electrical paths within other parts of the acoustic wave device (e.g. including interconnects within the cavity package), which may be problematic due to issues arising from the mismatch in coefficients of thermal expansion (CTEs) of different materials.

The acoustic device according to a number of embodiments comprises the multi-layer piezoelectric substrate. The multi-layer piezoelectric substrate of such an acoustic device may optionally have a side on which at least one first electrode 112 is formed. Such at least one first electrode 112 may be formed on a side of the multi-layer piezoelectric substrate that corresponds to a surface of the piezoelectric layer 122. The at least one first electrode 112 may be physically coupled to the at least one electrical interconnect 114. One or more of the one first electrodes 112 may be provided in the form of IDTs 112.

Alternatively, the at least one first electrode 112 may form a part of the multi-layer piezoelectric substrate. In such cases, the at least one first electrode 112 may optionally be at least part-embedded in a layer of the multi-layer piezoelectric substrate, such as the piezoelectric layer 122.

As shown FIG. 1, the substrate layer 128 has at least one electrical connection 116 extending through the thickness of the substrate layer 128. Optionally, at least a part of the at least one electrical connection 116 may be provided in forms of one or more electrical vias, such as one or more through-silicon via (TSVs). One or more of the at least one electrical connection 116 and one or more of the at least one electrical interconnect 114 are electrically connected. Said electrical connection(s) may be made by physical coupling (i.e. by one or more direct physical contacts) or via any suitable type of electrical connection(s).

Thus, the at least one first electrode 112 may be electrically connected with the at least one electrical connection 116 via the at least one electrical interconnect 114.

Optionally, the substrate layer 128 may be any suitable substrate, such as a Si substrate, a III-V semiconductor substrate, a II-VI semiconductor substrate, or a quartz substrate. Optionally, the substrate layer 128, and/or other layers of the multi-layer piezoelectric substrate may comprise dopants for achieving desired acoustic, mechanical, electrical, and/or optical properties.

The acoustic device according to a number of embodiments comprises the multi-layer piezoelectric substrate. The multi-layer piezoelectric substrate of such an acoustic device may optionally have a side on which at least one second electrode 118 is formed. Such at least one second electrode 118 may be formed on a side of the multi-layer piezoelectric substrate that corresponds to a surface of the substrate layer 128. The at least one second electrode 118 may be physically coupled to the at least one electrical connection 116. One or more of the one second electrodes 118 may be provided in forms of electrical terminals.

Alternatively, the at least one second electrode 118 may form a part of the multi-layer piezoelectric substrate. In such cases, the at least one second electrode 118 may optionally be at least part-embedded in a layer of the multi-layer piezoelectric substrate, such as the substrate layer 128.

Thus, the at least one second electrode 118 may be electrically connected with the at least one electrical interconnect 114 via the at least one electrical connection 116.

Optionally, the multi-layer piezoelectric substrate may comprise a plurality of the electrical terminals 112 on a second side of the multi-layer piezoelectric substrate. In such cases, each of the electrical terminals 112 may be electrically connected with the at least one first electrode 112 on a first side of the multi-layer piezoelectric substrate (i.e. a side of the multi-layer piezoelectric substrate that is facing away from the second side) via the at least one electrical interconnect 114 and the at least one electrical connection 116.

The layers and the electrical connections of the multi-layer piezoelectric substrate may be formed or provided in sequence starting from the substrate layer 128. However, depending on the exact structures and/or material properties, such an approach may accompany challenges such as those arising from the mismatch in CTEs of different materials, complexity of fabrication processes, manufacturing cost, and yield.

In view of this, the multi-layer piezoelectric substrate may be formed in a plurality of parts, and then bonded to form a single multi-layer piezoelectric substrate. In such cases, the multi-layer piezoelectric substrate may comprise one or more layers that can function as bonding layer(s) during the fabrication process. Such bonding layer(s) may enable physical coupling with one or more adjacent layers. Such bonding layers may have additional functions. For example, in embodiments having one or more layers comprising SiO₂ (e.g. the example of FIG. 1), at least one of the SiO₂ layers may be used as bonding layer(s) during fabrication process as well as a temperature coefficient of frequency (TCF) layer for providing thermal compensation, and enhancing device performance and reliability.

It will be appreciated that any other suitable bonding materials other than SiO₂ may also be used, and the choice of the bonding materials and exact method of the bonding process may vary depending on factors such as the materials and structures of the multi-layer piezoelectric substrate and/or acoustic wave device.

If one or more bonding layers are in present in the multi-layer piezoelectric substrate, one or more the electrical interconnects 114 extending through the piezoelectric layer 122 and the at least one dielectric layer 124 may also extend through the bonding layer(s).

Optionally, the dielectric materials forming the dielectric layer(s) 124 of the multi-layer piezoelectric substrate may comprise one or more of: SiO2, silicon nitride (Si₃N₄), silicon carbide (SiC), and any other suitable dielectric material(s). The multi-layer piezoelectric substrate may also comprise a plurality of dielectric layers 124 made of different materials.

Optionally, the materials forming the conductive elements (e.g. electrical interconnect 114, electrical connection 116, and electrodes 116, 118) may be made of any conductive material(s), such as Cu, Al, Mo, Au, or a metal alloy. The conductive elements of the multi-layer piezoelectric substrate and/or the acoustic device may vary in their material types, compositions, and/or contents.

Optionally, the piezoelectric materials forming the piezoelectric layer(s) 122 of the multi-layer piezoelectric substrate may comprise one or more of: LiNbO₃, LiTaO₃, and any other suitable piezoelectric material(s). The multi-layer piezoelectric substrate may also comprise a plurality of piezoelectric layers 122 made of different materials.

The acoustic wave device, comprising the multi-layer piezoelectric substrate, may further comprise one or more acoustic components. Such acoustic component(s) may be positioned on one or more sides of the multi-layer piezoelectric substrate along with the first electrode(s) 114 and/or the second electrode(s) 118. Alternatively, one or more of the acoustic component(s) may be at least part-embedded in a layer of the multi-layer piezoelectric substrate, such as the piezoelectric layer 122 or the substrate layer 128.

Optionally, the acoustic wave device may comprise a cavity package 130. Such a cavity package may be coupled to a side of the multi-layer piezoelectric substrate, such as the side of the multi-layer piezoelectric substrate corresponding to a surface of the piezoelectric layer(s) 122.

The cavity package(s) may provide one or more cavity structures defining one or more cavities between the multi-layer piezoelectric substrate and the cavity package(s). Alternatively, the acoustic wave device may comprise separate cavity structure(s) and packaging structure(s).

The cavity package(s) may be a front-side package with one or more terminals. Such a front-side package configuration may provide electrical connections from the top. Alternatively, the cavity package(s) my comprise a front-side lid with one or more cavities. Such a cavity may be provided in a form of an active structure or a simple lid.

The multi-layer piezoelectric substrate may provide a substrate on which acoustic and/or electrical component(s) may be positioned to form an acoustic wave device. Additionally, or alternatively, the multi-layer piezoelectric substrate may also provide a substrate having acoustic and/or electrical component(s) integrated therein, thereby reducing the complexity and/or number of subsequent steps for manufacturing an acoustic wave device. The acoustic wave device, comprising the multi-layer piezoelectric substrate may be configured to function as one or more of: a bulk acoustic wave device, a film bulk acoustic resonator, a solidly mounted resonator, and a surface acoustic wave device.

As briefly described above, the multi-layer piezoelectric substrate may be formed using bonding techniques. In other words, the multi-layer piezoelectric substrate may be formed by providing a plurality of parts of the multi-layer piezoelectric substrate and then bonding said plurality of parts into a single substrate.

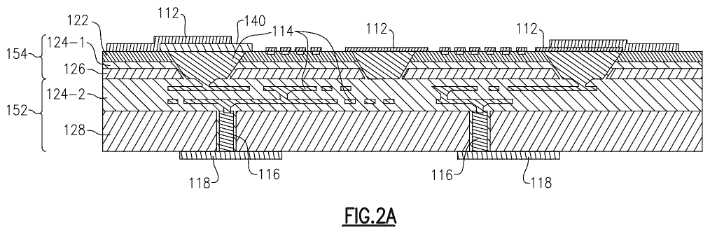

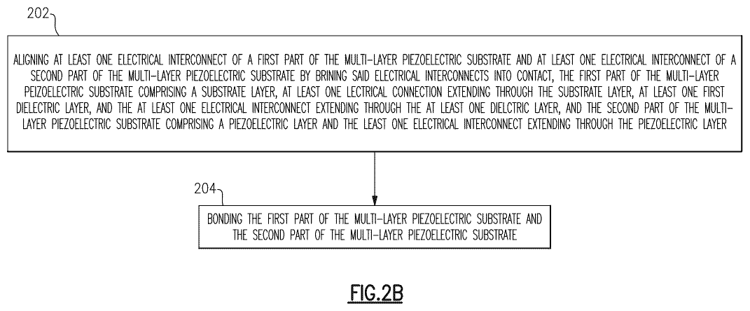

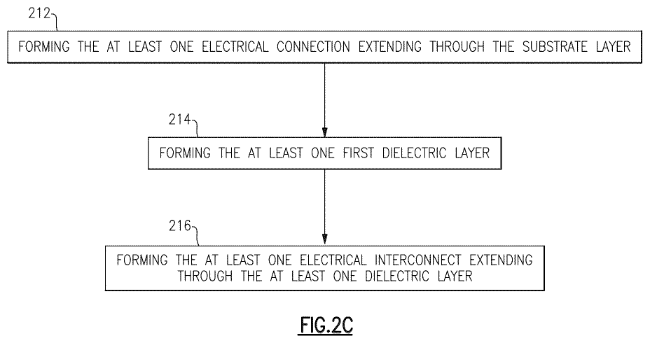

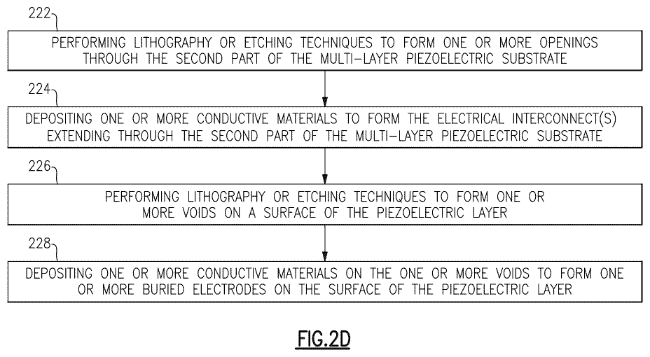

For example, as shown in the flow chart of FIG. 2B, the multi-layer piezoelectric substrate may be formed using a method comprising: providing a first part 152 of the multi-layer piezoelectric substrate comprising a substrate layer 128, at least one electrical connection 116 extending through the substrate layer 128, at least one first dielectric layer 124, and at least one electrical interconnect 114 extending through the at least one dielectric layer 124; providing a second part 154 of the multi-layer piezoelectric substrate comprising a piezoelectric layer 122 and at least one electrical interconnect 114 extending through the piezoelectric layer 122; and bonding the first and first parts 152, 154 of multi-layer piezoelectric substrate to align the at least one electrical interconnect 114 extending through the at least one dielectric layer 124 and the at least one electrical interconnect 114 extending through the piezoelectric layer 122. An exemplary multi-layer piezoelectric substrate formed using the said method (without the package cavity) is shown in an FIG. 2A.

The first part 152 of the multi-layer may be formed prior to the bonding step. For example, prior to the bonding, the first part 152 may be formed by a method comprising the steps of: providing the substrate layer 128; forming the at least one electrical connection 116 extending through the substrate layer 128; forming the at least one first dielectric layer 124; and forming the at least one electrical interconnect 114 extending through the at least one dielectric layer 124.

Optionally, prior to the bonding step, the at least one electrode 118 may be formed on a side of the substrate layer 128. Alternatively, the at least one electrode 118 may be formed after the bonding step.

As shown in the example of FIG. 1, the first part 152 may have the at least one electrode 118 formed thereon, which is electrically connected with the at least one electrical interconnect 114 via the at least one electrical connection 116. The at least one electrode 118 may be physically coupled to the at least one electrical connection 116 and may also be provided in the form of one or more electrical terminals 112.

Similarly, the second part 154 of the multi-layer piezoelectric substrate may be formed prior to the bonding step. For example, prior to the bonding, the second part 154 may be formed by a method comprising the steps of: forming the piezoelectric layer 122; and forming the at least one electrical interconnect 114 extending through the piezoelectric layer 122.

Optionally, the piezoelectric layer 122 may be formed on a substrate. In such cases, said substrate may be removed after the step of bonding of the first and first parts 152, 154 of multi-layer piezoelectric substrate. Such removal may be performed by, for example, using milling and/or lift-off techniques. In such cases, the second part 154 of the multi-layer piezoelectric substrate may further comprise one or more sacrificial layers for enabling and/or minimizing the damage caused by the removal process.

Furthermore, as shown in FIG. 2A, the second part of the multi-layer piezoelectric substrate may comprise one or more Metal-Insulator-Metal Capacitors (MIMCap) 140, 112 formed thereon. Such MIMCap structures comprise a dielectric layer 140 (e.g. SiO₂, Si₃N₄, or SiC). Such a dielectric layer 140 may be formed by using dielectric deposition in conjunction with lithography or dry etching techniques. Such MIMCap structures also comprise a top metal layer 112 which may provide a probing pad layer.

Thus, as shown in the flowchart of FIG. 2C, forming the second part 154 of the multi-layer piezoelectric substrate may, for example, comprise: the steps of performing lithography or etching techniques to form one or more openings through the second part 154 of the multi-layer piezoelectric substrate; and depositing one or more conductive materials to form the electrical interconnect(s) extending through the second part 154 of the multi-layer piezoelectric substrate. Such lithography and/or etching techniques may be performed with or without a hardmask. Optionally, a liner layer may be deposited prior to the step of depositing the one or more conductive materials to form the electric interconnect(s). Optionally, following the step of depositing the one or more conductive materials, chemical mechanical polishing or chemical mechanical planarization techniques may be performed to remove excess materials and/or achieve desired profile of deposited materials. Such techniques may also be applicable for forming other parts and/or elements of the multi-layer piezoelectric substrate.

Optionally, the multi-layer piezoelectric substrate may comprise one or more buried electrodes on a surface of the piezoelectric. As shown in the flowchart of FIG. 2D, forming such buried electrodes may comprise the steps of performing lithography or etching techniques to form one or more voids on a surface of the piezoelectric layer; and depositing one or more conductive materials on the one or more voids to form one or more buried electrodes on the surface of the piezoelectric layer.

Optionally, the second part 154 of the multi-layer piezoelectric substrate may be or form a part of a front-end portion of the multi-layer piezoelectric substrate.

Optionally, prior to the bonding step, the at least one electrode 112 may be formed on a side of the piezoelectric layer 122. Alternatively, the at least one electrode 112 may be formed after the bonding step.

As shown in the example of FIGS. 1 and 2, the second part 154 may have the at least one electrode 112 formed thereon, which is electrically connected with the at least one electrical interconnect 114. The at least one electrode 112 may be physically coupled to the at least one electrical interconnect 114 and may also be provided in forms of one or more IDTs 112.

Optionally, one or more of the plurality of the parts of the multi-layer piezoelectric substrate may comprise one or more bonding layers. For example, the multi-layer piezoelectric substrate shown in FIG. 1, may require either or both of the first part 152 and second part 154 of the multi-layer piezoelectric substrate to have one or more layers configured to function as bonding layer(s) for bonding the first and first parts 152, 154 of multi-layer piezoelectric substrate.

The at least one electrical connection 116 extending through the substrate layer 128, the at least one electrical interconnect 114 extending through the at least one dielectric layer 124, and/or the at least one electrical interconnect 114 extending through the piezoelectric layer 122 may be formed prior to the step of bonding of the first and second parts 152, 154 of multi-layer piezoelectric substrate. This may be advantageous particularly if the resulting multi-layer piezoelectric substrate is of high thickness, which may make through-thickness metal deposition proves (e.g. the damascene process) challenging.

Alternatively, they may be formed after the step of bonding of the first and second parts 152, 154 of multi-layer piezoelectric substrate if, for example, the resulting multi-layer piezoelectric substrate is of relatively low thickness.

Accordingly, the acoustic wave device may be formed by forming one or more acoustic wave device components on the multi-layer piezoelectric substrate. It will be appreciated that the one or more acoustic wave device components may include: one or more resonator structures, one or more bulk acoustic wave device components, one or more film bulk acoustic resonator components, one or more solidly mounted resonator components, one or more surface acoustic wave device components, one or more electrical connections and/or electrodes, and/or one or more cavity packages 130.

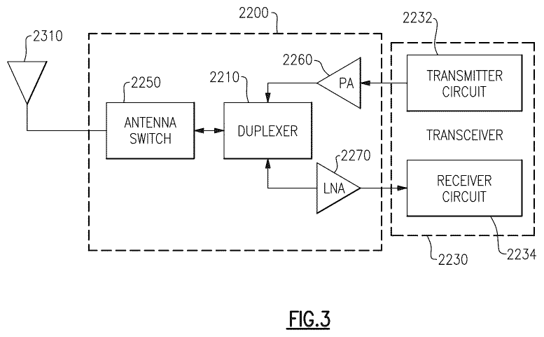

The substrate shown in FIG. 1, or the acoustic device such as that of FIG. 1, may also be included in a radio-frequency front end (RFFE) module. An exemplary RFFE module is shown in FIG. 3. This figure illustrates a front-end module 2200, connected between an antenna 2310 and a transceiver 2230. The front-end module 2200 includes a duplexer 2210 in communication with an antenna switch 2250, which itself is in communication with the antenna 2310.

As illustrated, the transceiver 2230 comprises a transmitter circuit 2232. Signals generated for transmission by the transmitter circuit 2232 are received by a power amplifier (PA) module 2260 within the front-end module 2200 which amplifies the generated signals from the transceiver 2230. The PA module 2260 can include one or more PAs. The PA module 2260 can be used to amplify a wide variety of RF or other frequency-band transmission signals. For example, the PA module 2260 can receive an enable signal that can be used to pulse the output of the PE to aid in transmitting a wireless local area network (WLAN) signal or any other suitable pulsed signal. The PA module 2260 can be configured to amplify any of a variety of types of signals, including, for example, a Global System for Mobile (GSM) signal, a code division multiple access (CDMA) signal, a W-CDMA signal, a Long-Term Evolution (LTE) signal, or an EDGE signal.

In certain embodiments, the PA module 2260 and associated components including switches and the like can be fabricated on gallium arsenide (GaAs) substrates using, for example, high electron mobility transistors (pHEMT) or insulated-gate bipolar transistors (BiFET), or on a silicon substrate using complementary metal-oxide semiconductor (CMOS) field effect transistors (FETs).

Still referring to FIG. 3, the front-end module 2200 may further include a low noise amplifier (LNA) module 2270, which amplifies received signals from the antenna 2310 and provides the amplified signals to the receiver circuit 2234 of the transceiver 2230.

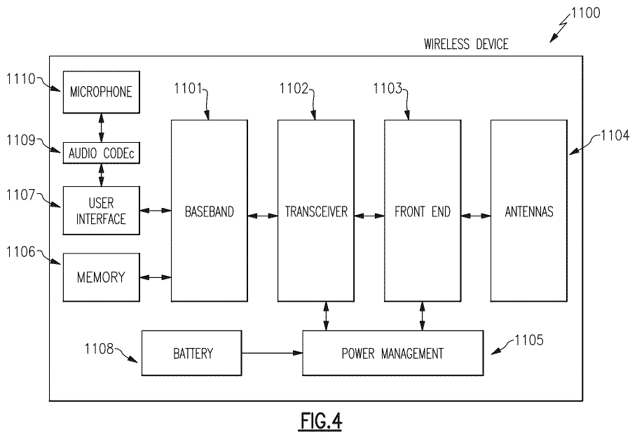

FIG. 4 is a schematic diagram of a wireless device 1100 that can incorporate aspects of the invention. The wireless device 1100 can be, for example, but not limited to, a portable telecommunication device such as a mobile cellular-type telephone. The wireless device 1100 can include a microphone arrangement 1100, and may include one or more of a baseband system 1101, a transceiver 1102, a front-end system 1103 (such as the front-end module 2200 of FIG. 10, one or more antennas 1104, a power management system 1105, a memory 1106, a user interface 1107, a battery 1108, and audio codec 1109. The microphone arrangement may supply signals to the audio codec 1109 which may encode analog audio as digital signals or decode digital signals to analog. The audio codec 1109 may transmit the signals to a user interface 1107. The user interface 1107 transmits signals to the baseband system 1101. The transceiver 1102 generates RF signals for transmission and processes incoming RF signals received from the antennas. The front-end system 1103 aids in conditioning signals transmitted to and/or received from the antennas 1104. The antennas 1104 can include antennas used for a wide variety of types of communications. For example, the antennas 1104 can include antennas 1104 for transmitting and/or receiving signals associated with a wide variety of frequencies and communications standards. The baseband system 1101 is coupled to the user interface to facilitate processing of various user input and output, such as voice and data. The baseband system 1101 provides the transceiver 1102 with digital representations of transmit signals, which the transceiver 1102 processes to generate RF signals for transmission. The baseband system 1101 also processes digital representations of received signals provided by the transceiver 1102.

As shown in FIG. 4, the baseband system 1101 is coupled to the memory 1106 to facilitate operation of the wireless device 1100. The memory 1106 can be used for a wide variety of purposes, such as storing data and/or instructions to facilitate the operation of the wireless device 1100 and/or to provide storage of user information. The power management system 1105 provides a number of power management functions of the wireless device 1100. The power management system 1105 receives a battery voltage from the battery 1108. The battery 1108 can be any suitable battery for use in the wireless device, including, for example, a lithium-ion battery.

Having described above several aspects of at least one embodiment, it is to be appreciated various alterations, modifications, and improvements will readily occur to those skilled in the art. Such alterations, modifications, and improvements are intended to be part of this disclosure and are intended to be within the scope of the invention. Accordingly, the foregoing description and drawings are by way of example only, and the scope of the invention should be determined from proper construction of the appended claims, and their equivalents.

What is claimed is:

1. A multi-layer piezoelectric substrate comprising:
a piezoelectric layer;
at least one dielectric layer;
at least one electrical interconnect extending through the piezoelectric layer and the at least one dielectric layer; and
a substrate layer having at least one electrical connection extending through the substrate layer, the at least one electrical connection and the at least one electrical interconnect being electrically connected.

2. The multi-layer piezoelectric substrate of claim 1 further comprising at least one first electrode on a first side of the substrate and electrically connected with the at least one electrical connection via the at least one electrical interconnect.

3. The multi-layer piezoelectric substrate of claim 1 further comprising at least one first electrode on a first side of the substrate and physically coupled to the at least one electrical interconnect.

4. The multi-layer piezoelectric substrate of claim 1 further comprising at least one second electrode on a second side of the substrate and electrically connected with the at least one electrical interconnect via the at least one electrical connection.

5. The multi-layer piezoelectric substrate of claim 1 further comprising at least one second electrode on a second side of the substrate and physically coupled to the at least one electrical connection.

6. The multi-layer piezoelectric substrate of claim 1 comprising a plurality of electrical terminals on a second side of the multi-layer piezoelectric substrate, each of the plurality of electrical terminals being electrically connected with at least one first electrode on a first side of the multi-layer piezoelectric substrate via the at least one electrical interconnect and the at least one electrical connection, the first side of the multi-layer piezoelectric substrate facing away from the second side of the multi-layer piezoelectric substrate.

7. The multi-layer piezoelectric substrate of claim 1 further comprising at least one bonding layer for providing physical coupling with one or more adjacent layers, the at least one electrical interconnect extending through the piezoelectric layer, the at least one dielectric layer, and the at least one bonding layer.

8. The multi-layer piezoelectric substrate of claim 1 comprising a first dielectric layer, a second dielectric layer, and a polysilicon layer between the first dielectric layer and the second dielectric layer.

9. The multi-layer piezoelectric substrate of claim 8 wherein at least one of the first dielectric layer and the second dielectric layer is configured to function as a bonding layer for providing physical coupling with one or more adjacent layers.

10. The multi-layer piezoelectric substrate of claim 8 wherein the first dielectric layer is positioned between the piezoelectric layer and the polysilicon layer, and the second dielectric layer is positioned between the polysilicon layer and the substrate layer.

11. The multi-layer piezoelectric substrate of claim 8 comprising:
one or more first electrical interconnects extending through the piezoelectric layer, the first dielectric layer, and the polysilicon layer; and
one or more second electrical interconnects extending through the second dielectric layer.

12. An acoustic device comprising:
a multi-layer piezoelectric substrate including a piezoelectric layer, at least one dielectric layer, at least one electrical interconnect extending through the piezoelectric layer and the at least one dielectric layer, and a substrate layer having at least one electrical connection extending through the substrate layer, the at least one electrical connection and the at least one electrical interconnect being electrically connected.

13. A method of forming a multi-layer piezoelectric substrate, the method comprising:
aligning at least one electrical interconnect of a first part of the multi-layer piezoelectric substrate and at least one electrical interconnect of a second part of the multi-layer piezoelectric substrate by bringing the at least one electrical interconnect into contact,
the first part of the multi-layer piezoelectric substrate comprising a substrate layer, at least one electrical connection extending through the substrate layer, at least one first dielectric layer, and the at least one electrical interconnect extending through the at least one first dielectric layer, and
the second part of the multi-layer piezoelectric substrate including a piezoelectric layer and the least one electrical interconnect extending through the piezoelectric layer; and
bonding the first part of the multi-layer piezoelectric substrate and the second part of the multi-layer piezoelectric substrate.

14. The method of claim 13 wherein the first part of the multi-layer piezoelectric substrate is formed by steps comprising:
forming the at least one electrical connection extending through the substrate layer;
forming the at least one first dielectric layer; and
forming the at least one electrical interconnect extending through the at least one first dielectric layer.

15. The method of claim 14 further comprising forming at least one electrode on a side of the substrate layer electrically connected with the at least one electrical interconnect via the at least one electrical connection.

16. The method of claim 14 further comprising forming at least one electrode on a side of the substrate layer physically coupled to the at least one electrical connection.

17. The method of claim 13 wherein the second part of the multi-layer piezoelectric substrate is formed by steps comprising:
forming the piezoelectric layer; and
forming the at least one electrical interconnect extending through the piezoelectric layer.

18. The method of claim 17 wherein the piezoelectric layer is formed on a substrate, the method further comprising removing the substrate on which the piezoelectric layer is formed after bonding of the first and second parts of multi-layer piezoelectric substrate.

19. The method of claim 13 wherein forming the second part of the multi-layer piezoelectric substrate includes:
performing lithography or etching techniques to form one or more openings through the second part of the multi-layer piezoelectric substrate; and
depositing one or more conductive materials to form the at least one electrical interconnect extending through the second part of the multi-layer piezoelectric substrate.

20. The method of claim 13 wherein forming the second part of the multi-layer piezoelectric substrate comprises:
performing lithography or etching techniques to form one or more voids on a surface of the piezoelectric layer; and
depositing one or more conductive materials on the one or more voids to form one or more buried electrodes on the surface of the piezoelectric layer.
